(19) United States
(12) Patent Application Publication
(10) Pub. No.: US 2023/0241723 A1
(43) Pub. Date: Aug. 3, 2023

(54) WAFER MANUFACTURING APPARATUS

(71) Applicant: DISCO CORPORATION, Tokyo (JP)

(72) Inventor: Keiji NOMARU, Tokyo (JP)

(21) Appl. No.: 18/152,878

(22) Filed: Jan. 11, 2023

(30) Foreign Application Priority Data
Jan. 31, 2022 (JP) 2022-013216

(51) Int. Cl. B23K 26/53; B23K 26/06

(52) U.S. Cl. CPC B23K 26/53; B23K 26/0665; B23K 26/083

(57) ABSTRACT

A wafer manufacturing apparatus includes a holding table that holds an ingot, a wafer manufacturing unit that applies such a laser beam as to be transmitted through the ingot to the ingot, with a focal point of the laser beam positioned inside the ingot, to form a modified layer at a depth corresponding to the thickness of a wafer to be manufactured, and a moving mechanism that moves the holding table and the wafer manufacturing unit relative to each other. The wafer manufacturing unit includes a laser oscillator that emits the laser beam, a condenser lens that concentrates the laser beam emitted by the laser oscillator, to the inside of the ingot, and a rotating mechanism that rotates the condenser lens in parallel to an end face of the ingot.

### BACKGROUND OF THE INVENTION

### Field of the Invention

The present invention relates to an apparatus for manufacturing a wafer.

### Description of the Related Art

Devices such as integrated circuits (ICs), large scale integration (LSI) circuits, and light emitting diodes (LEDs) are formed by a functional layer being laminated on a front surface of a wafer formed of a blank material such as silicon (Si) and sapphire (Al₂O₃) and the functional layer being partitioned by a plurality of intersecting streets. In addition, power devices, LEDs, and the like are formed by a functional layer being laminated on a front surface of a wafer formed of a blank material of hexagonal single crystal of silicon carbide (SiC), gallium nitride (GaN), or the like and the functional layer being partitioned by a plurality of intersecting streets.

The wafer formed with the devices is divided into individual device chips by being processed along the streets by a cutting apparatus or a laser processing apparatus, and the thus divided device chips are used for electronic apparatuses such as mobile phones and personal computers.

The wafer to be formed with the devices is typically manufactured by a cylindrical ingot being cut into a thin shape by a wire saw. A front surface and a back surface of the thus manufactured wafer are finished into a mirror surface by polishing (refer to, for example, Japanese Patent Laid-open 2000-94221).

Yet, cutting the ingot by a wire saw and polishing the front surface and the back surface of the cut wafer result in a majority (70% to 80%) of the ingot being thrown away, posing the problem of being economical. Especially, a single crystal ingot, such as SiC and GaN, which is high in hardness, is difficult to cut by a wire saw, requiring a considerable amount of time for processing and thus resulting in low productivity. Moreover, ingots being expensive also poses a challenge to efficient production of wafers.

As such, there has been proposed a technique of forming a modified layer in a planned cutting plane by positioning, inside an ingot, a focal point of such a laser beam as to be transmitted through SiC or the like and then applying the laser beam to the ingot, to thereby peel off a wafer from the ingot along the planned cutting plane in which the modified layer has been formed (see, for example, Japanese Patent Laid-open No. 2013-49161).

### SUMMARY OF THE INVENTION

However, there is a problem that modified layers should be formed densely with the interval of the modified layers being on the order of 10 μm, and it takes considerable time to form the modified layers, so that productivity is poor.

Accordingly, it is an object of the present invention to provide a wafer manufacturing apparatus capable of efficiently forming a modified layer inside an ingot.

In accordance with an aspect of the present invention, there is provided a wafer manufacturing apparatus including a holding table that holds an ingot, a wafer manufacturing unit that applies such a laser beam as to be transmitted through the ingot to the ingot, with a focal point of the laser beam positioned inside the ingot, to form a modified layer at a depth corresponding to the thickness of a wafer to be manufactured, and a moving mechanism that moves the holding table and the wafer manufacturing unit relative to each other, in which the wafer manufacturing unit includes a laser oscillator that emits the laser beam, a condenser lens that concentrates the laser beam emitted by the laser oscillator, to the inside of the ingot, and a rotating mechanism that rotates the condenser lens in parallel to an end face of the ingot.

Preferably, a plurality of the condenser lenses are disposed in the rotating direction.

According to the present invention, a modified layer can efficiently be formed inside an ingot.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a wafer manufacturing apparatus of an embodiment of the present invention;

FIG. 2A is a sectional view of a wafer manufacturing unit depicted in FIG. 1;

FIG. 2B is a bottom view of a rotary body depicted in FIG. 2A;

FIG. 3A is a perspective view of an ingot;

FIG. 3B is a plan view of the ingot depicted in FIG. 3A;

FIG. 3C is a front view of the ingot depicted in FIG. 3A;

FIG. 4A is a perspective view depicting a modified layer forming step;

FIG. 4B is a side view depicting the modified layer forming step;

FIG. 5 is a perspective view depicting a stripping step;

FIG. 6A is a sectional view depicting a first modification of the wafer manufacturing unit;

FIG. 6B is a bottom view of a rotary body depicted in FIG. 6A;

FIG. 7A is a sectional view depicting a second modification of the wafer manufacturing unit;

FIG. 7B is a bottom view of a rotary body depicted in FIG. 7A;

FIG. 8A is a sectional view depicting a third modification of the wafer manufacturing unit; and

FIG. 8B is a bottom view of a rotary body depicted in FIG. 8A.

### DETAILED DESCRIPTION OF THE PREFERRED EMBODIMENTS

A wafer manufacturing apparatus of an embodiment of the present invention will be described in detail below with reference to the drawings.

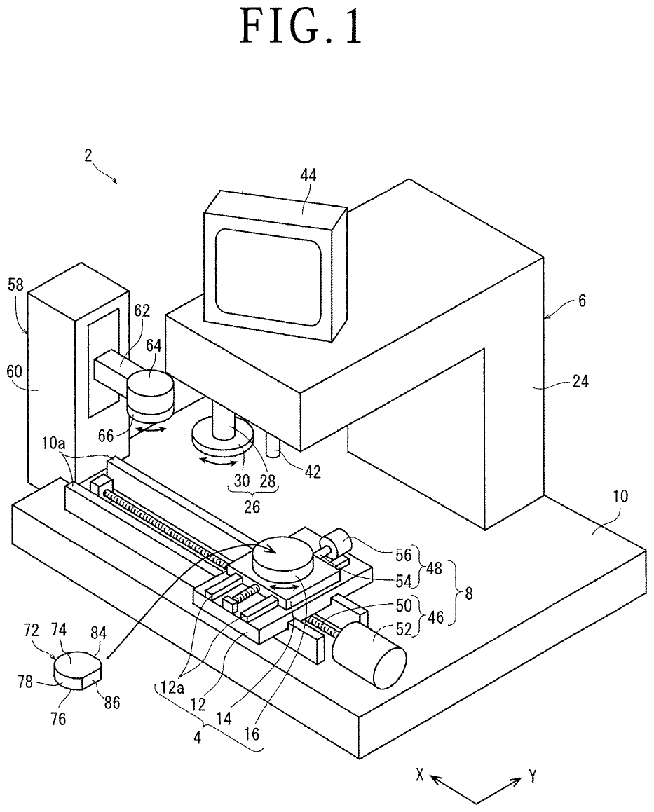

As illustrated in FIG. 1, a wafer manufacturing apparatus 2 includes at least a holding unit 4 that holds an ingot, a wafer manufacturing unit 6 that applies such a laser beam as to be transmitted through the ingot to the ingot, with a focal point of the laser beam positioned inside the ingot, to form a modified layer at a depth corresponding to the thickness of a wafer to be manufactured, and a moving mechanism 8 that moves the holding unit 4 and the wafer manufacturing unit 6 relative to each other.

The holding unit 4 includes an X-axis movable plate 12 supported by a base 10 in such a manner as to be movable in an X-axis direction, a Y-axis movable plate 14 supported on the X-axis movable plate 12 in such a manner as to be movable in a Y-axis direction, a holding table 16 supported on an upper surface of the Y-axis movable plate 14 in a rotatable manner, and a motor (not illustrated) that rotates the holding table 16.

Note that the X-axis direction is the direction indicated by an arrow X in FIG. 1, while the Y-axis direction is the direction indicated by an arrow Y in FIG. 1 and is a direction orthogonal to the X-axis direction. An XY plane defined by the X-axis direction and the Y-axis direction is substantially horizontal.

In the holding unit 4, the ingot is held on an upper surface of the holding table 16 through an appropriate adhesive (for example, an epoxy resin-based adhesive). Alternatively, the upper surface of the holding table 16 may be formed with a plurality of suction holes, and a suction force may be generated at the upper surface of the holding table 16 to hold under suction the ingot.

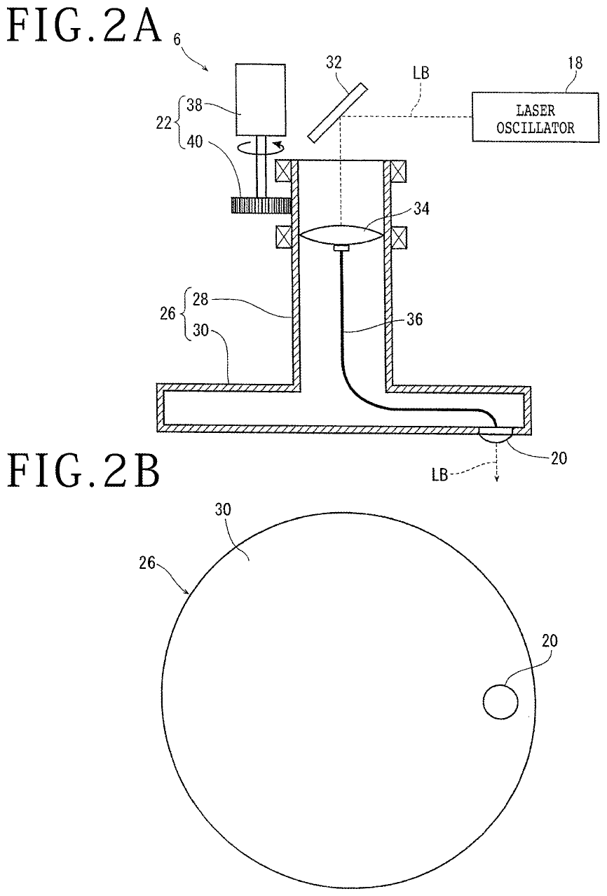

As depicted in FIG. 2A, the wafer manufacturing unit 6 includes a laser oscillator 18 that emits a laser beam LB, a condenser lens 20 that concentrates the laser beam LB emitted by the laser oscillator 18, to the inside of the ingot, and a rotating mechanism 22 that rotates the condenser lens 20 in parallel to an end face of the ingot.

As depicted in FIG. 1, the wafer manufacturing unit 6 has a housing 24 extending upward from an upper surface of the base 10 and then substantially horizontally, and the laser oscillator 18 is incorporated in the housing 24. The laser oscillator 18 is designed to emit a pulsed laser beam LB of such a wavelength as to be transmitted through the ingot which is a workpiece (for example, 1,064 nm in the case of a SiC ingot).

As depicted in FIGS. 1 and 2A, the wafer manufacturing unit 6 further has a hollow rotary body 26 disposed at a lower surface of a tip of the housing 24. The rotary body 26 includes an upper cylindrical section 28 supported in a rotatable manner on the lower surface of the tip of the housing 24 and a lower cylindrical section 30 spreading radially outward from a lower end of the upper cylindrical section 28. As depicted in FIGS. 2A and 2B, the condenser lens 20 is provided at a peripheral edge part of a lower surface of the lower cylindrical section 30 of the rotary body 26.

Between the laser oscillator 18 and the condenser lens 20, there are disposed a mirror 32 that reflects the laser beam LB emitted by the laser oscillator 18, a collimating lens 34 that converts the laser beam LB reflected by the mirror 32 into a parallel beam, and an optical fiber 36 that guides the laser beam LB transmitted through the collimating lens 34 to the condenser lens 20. The mirror 32 is provided inside the housing 24, and the collimating lens 34 and the optical fiber 36 are mounted to the rotary body 26.

As illustrated in FIG. 2A, the rotating mechanism 22 has a motor 38 and a gear 40 fixed to an output shaft of the motor 38. An outer peripheral surface of the upper cylindrical section 28 of the rotary body 26 is formed with a gear (not illustrated) that meshes with the gear 40 of the rotating mechanism 22. The rotating mechanism 22 rotates the rotary body 26 by the motor 38, whereby the condenser lens 20 is rotated in parallel to the end face of the ingot. Note that the mechanism for transmitting a rotational motion of the motor 38 to the rotary body 26 may be any other known mechanism.

As depicted in FIG. 1, on the lower surface of the tip of the housing 24, an imaging unit 42 for detecting a region to be processed with laser by the wafer manufacturing unit 6 is additionally provided. An image picked up by the imaging unit 42 is displayed on a monitor 44 disposed on an upper surface of the tip of the housing 24.

Continuously described with reference to FIG. 1, the moving mechanism 8 includes an X-axis feeding mechanism 46 that moves the holding unit 4 in the X-axis direction relative to the wafer manufacturing unit 6 and a Y-axis feeding mechanism 48 that moves the holding unit 4 in the Y-axis direction relative to the wafer manufacturing unit 6.

The X-axis feeding mechanism 46 has a ball screw 50 connected to the X-axis movable plate 12 and extending in the X-axis direction and a motor 52 for rotating the ball screw 50. The X-axis feeding mechanism 46 converts a rotational motion of the motor 52 into a rectilinear motion and transmits it to the X-axis movable plate 12 by the ball screw 50, and moves the X-axis movable plate 12 in the X-axis direction along guide rails 10a on the base 10.

The Y-axis feeding mechanism 48 has a ball screw 54 connected to the Y-axis movable plate 14 and extending in the Y-axis direction and a motor 56 for rotating the ball screw 54. The Y-axis feeding mechanism 48 converts a rotational motion of the motor 56 into a rectilinear motion and transmits it to the Y-axis movable plate 14 by the ball screw 54, and moves the Y-axis movable plate 14 in the Y-axis direction along guide rails 12a on the X-axis movable plate 12.

Further, the wafer manufacturing apparatus 2 of the present embodiment includes a peeling unit 58 that peels off a wafer from the ingot, along the modified layer formed at the depth corresponding to the thickness of the wafer to be manufactured.

The peeling unit 58 includes a casing 60 extending upward from end parts of the guide rails 10a on the base 10 and an arm 62 supported by the casing 60 in such a manner as to be liftable up and down and extending in the X-axis direction. In the casing 60, lifting means (not illustrated) for lifting the arm 62 up and down is incorporated.

A motor 64 is additionally disposed at the tip of the arm 62, and a suction piece 66 is connected to a lower surface of the motor 64 such as to be rotatable around an axis extending in the vertical direction. The suction piece 66 is connected to suction means (not illustrated), and a lower surface of the suction piece 66 is formed with a plurality of suction holes (not illustrated). In addition, ultrasonic vibration imparting means (not illustrated) that imparts ultrasonic vibration to the lower surface of the suction piece 66 is incorporated in the suction piece 66.

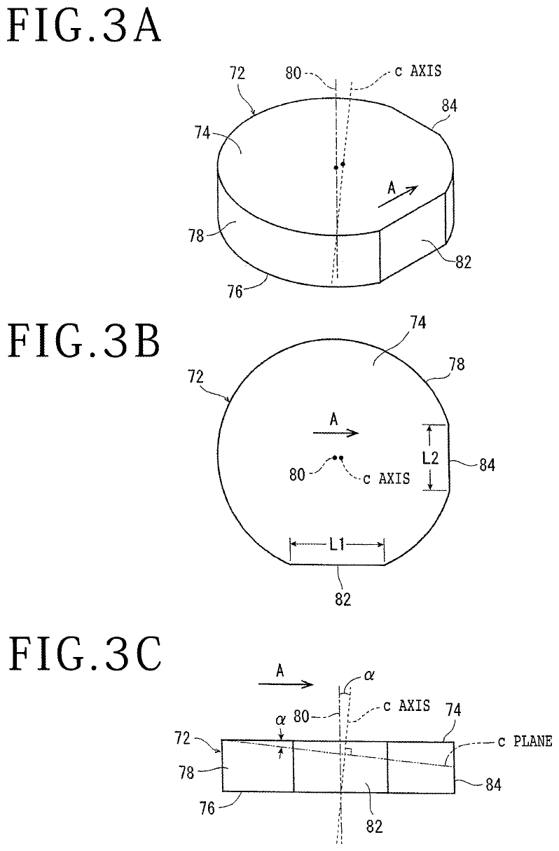

FIG. 3A depicts an ingot 72 to be processed by the above-described wafer manufacturing apparatus 2. The ingot 72 illustrated is formed of single crystal SiC.

The cylindrical ingot 72 has a circular first end face 74, a circular second end face 76 located on the opposite side of the first end face 74, a circumferential surface 78 located between the first end face 74 and the second end face 76, a c axis extending from the first end face 74 to the second end face 76, and a c plane (see FIG. 3C) orthogonal to the c axis. At least the first end face 74 is planarized by grinding or polishing to such an extent as not to hamper the incidence of a laser beam LB.

In the ingot 72, the c axis is inclined against a perpendicular 80 to the first end face 74, and an off angle α (for example, α=1, 3, or 6 degrees) is formed by the c plane and the first end face 74. The direction in which the off angle α is formed is indicated by an arrow A in FIGS. 3A to 3C.

The circumferential surface 78 of the ingot 72 is formed with a rectangular first orientation flat 82 and a second orientation flat 84 both of which indicate crystal orientation. The first orientation flat 82 is parallel to the direction A in which the off angle α is formed, while the second orientation flat 84 is orthogonal to the direction A in which the off angle α is formed. As depicted in FIG. 3B, when viewed from above, the length L2 of the second orientation flat 84 is shorter than the length L1 of the first orientation flat 82 (L2<L1).

Note that the ingot to be processed by the wafer manufacturing apparatus of the present invention is not limited to the ingot 72, and may be a SiC ingot in which the c axis is not inclined against the perpendicular to the first end face and the off angle α between the c plane and the first end face is 0 degrees (in other words, the perpendicular to the first end face and the c axis may coincide with each other), or may be an ingot formed of a material other than SiC such as Si or GaN.

Next, the method of manufacturing a wafer from the ingot 72 by use of the above-mentioned wafer manufacturing apparatus 2 will be described.

In the present embodiment, first, a holding step of holding the ingot 72 by the holding unit 4 is performed. In the holding step, with the first end face 74 directed upward, the ingot 72 is fixed to the upper surface of the holding table 16 through an appropriate adhesive (for example, an epoxy resin-based adhesive). Note that the upper surface of the holding table 16 may be formed with a plurality of suction holes, and a suction force may be generated at the upper surface of the holding table 16 to hold under suction the ingot 72.

After the holding step has been carried out, next performed is a modified layer forming step in which such a laser beam LB as to be transmitted through the ingot 72 is applied to the ingot 72, with a focal point of the laser beam LB positioned inside the ingot 72, to form a modified layer at a depth corresponding to the thickness of the wafer to be manufactured.

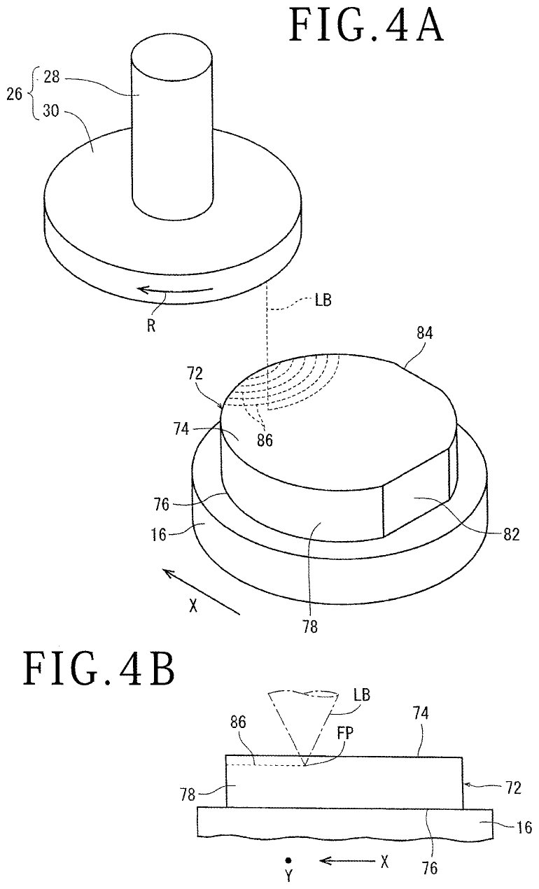

In the modified layer forming step, first, the X-axis feeding mechanism 46 is operated to position the holding table 16 directly under the imaging unit 42. Next, the ingot 72 is imaged by the imaging unit 42, and the positional relation between the ingot 72 and the rotary body 26 is adjusted in reference to the image of the ingot 72 picked up by the imaging unit 42. Subsequently, a focal point FP (see FIG. 4B) is positioned at a depth (for example, on the order of 500 pm) corresponding to the thickness of the wafer to be manufactured.

Next, while the rotary body 26 is rotated by the rotating mechanism 22 in the direction indicated by an arrow R in FIG. 4A and the holding table 16 is put into processing feeding in the X-axis direction, the laser beam LB of such a wavelength as to be transmitted through the ingot 72 is applied through the condenser lens 20 to the ingot 72. In other words, while the condenser lens 20 is rotated in parallel to the first end face 74 of the ingot 72 and the ingot 72 is moved in the X-axis direction, the laser beam LB is applied.

As a result, a multiplicity of arcuate modified layers 86 in which SiC is separated into Si and carbon (C) can efficiently be formed in parallel to the first end face 74. Note that, though not illustrated, cracks extend from the modified layers 86.

Such a modified layer forming step can be carried out, for example, under the following conditions.
Wavelength of pulsed laser beam: 1,064 nm
Average output: 6.0 W
Repetition frequency: 5 MHz
Pulse width: 10 ps
Numerical aperture of condenser lens (NA): 0.8
Rotation of condenser lens: 20 Hz

Note that, in the modified layer forming step, it is preferable to dispose a beam damper for absorbing the laser beam LB in the periphery of the ingot 72. By this, it is possible to prevent application of the laser beam LB to parts other than the ingot 72 such as the holding table 16 and damaging of the holding table 16 or the like.

Alternatively, the laser beam LB may be applied when the focal point FP is located inside the ingot 72, whereas the application of the laser beam LB may be stopped when the focal point FP is located outside the ingot 72.

After the modified layer forming step has been performed, a peeling step in which a wafer is peeled off from the ingot 72 along the modified layer 86 formed at a depth corresponding to the thickness of the wafer to be manufactured is carried out.

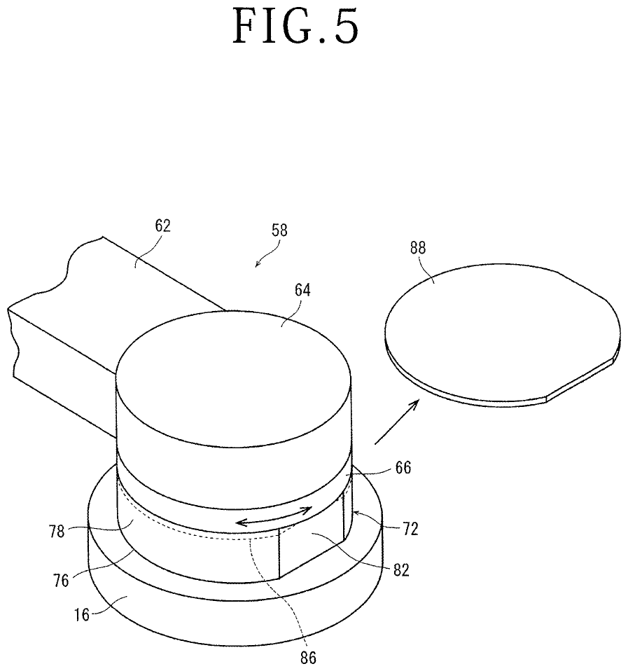

In the peeling step, first, the X-axis feeding mechanism 46 is operated to position the holding table 16 on the lower side of the suction piece 66 of the peeling unit 58. Next, as depicted in FIG. 5, the arm 62 is lowered to bring the lower surface of the suction piece 66 into close contact with an upper surface (the first end face 74) of the ingot 72. Subsequently, the suction means is operated to bring the lower surface of the suction piece 66 into close contact with the upper surface of the ingot 72.

Then, the ultrasonic vibration imparting means is operated to impart ultrasonic vibration to the lower surface of the suction piece 66, and the suction piece 66 is rotated by the motor 64. As a result, a wafer 88 can be peeled off from the ingot 72 along the modified layer 86 formed at the depth corresponding to the thickness of the wafer to be manufactured. Note that, after the wafer 88 is peeled off, the peeling surface of the ingot 72 and the peeling surface of the wafer 88 are planarized by grinding or polishing.

As has been described above, the wafer manufacturing unit 6 of the present embodiment includes the laser oscillator 18 that emits the laser beam LB, the condenser lens 20 that concentrates the laser beam LB emitted by the laser oscillator 18, to the inside of the ingot 72, and the rotating mechanism 22 that rotates the condenser lens 20 in parallel to the end face of the ingot 72, so that it is possible to efficiently form the modified layer 86 inside the ingot 72.

(First Modification)

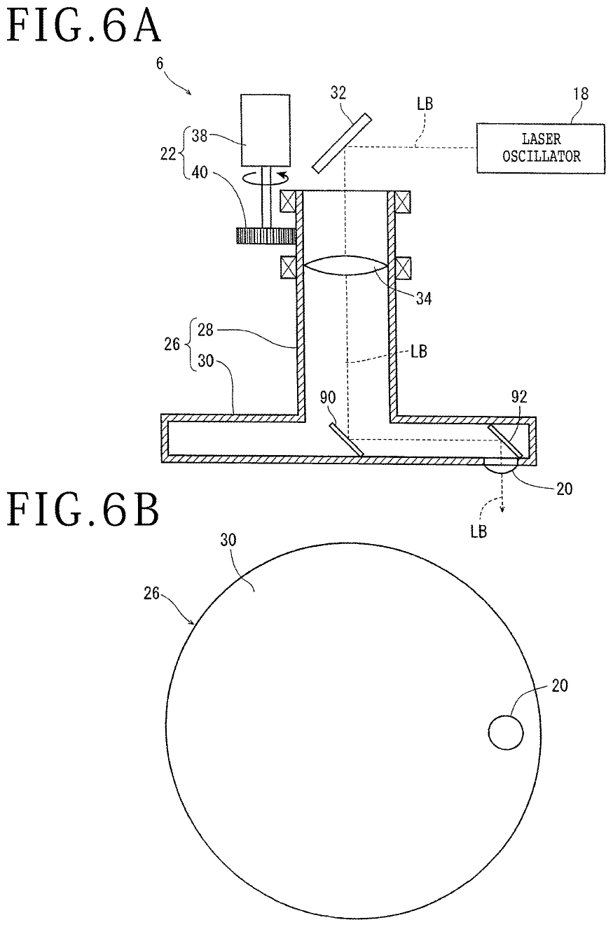

Note that the wafer manufacturing unit 6 of the present invention is not limited to the above-described form. For example, in place of the optical fiber 36 depicted in FIG. 2A, as depicted in a first modification illustrated in FIG. 6A, first and second mirrors 90 and 92 for guiding to the condenser lens 20 the laser beam LB transmitted through the collimating lens 34 may be disposed between the collimating lens 34 and the condenser lens 20.

(Second Modification)

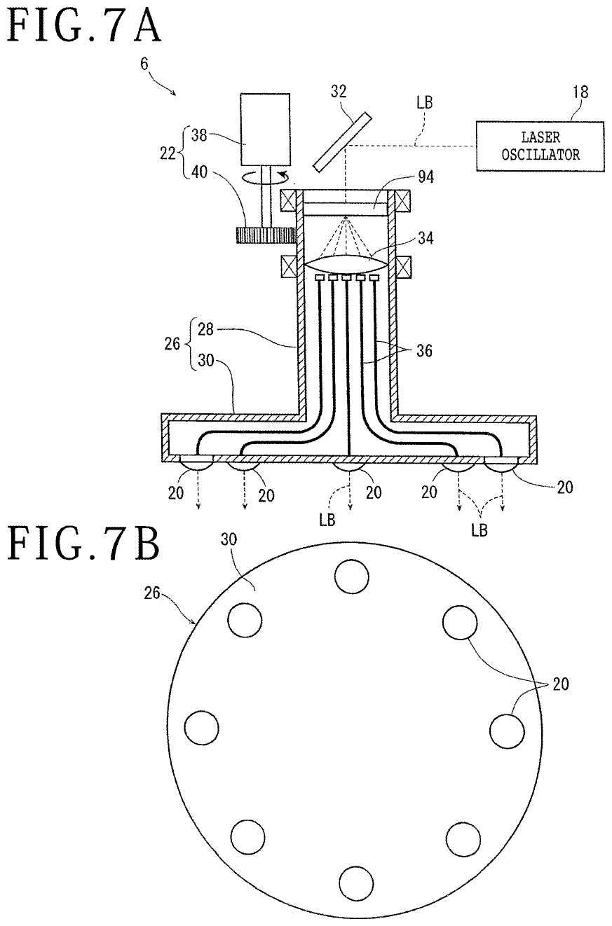

In a second modification depicted in FIGS. 7A and 7B, a plurality of condenser lenses 20 are disposed at intervals in the rotating direction of the rotary body 26. While eight condenser lenses 20 are disposed in the second modification, the number and the intervals of the condenser lenses 20 can be set as desired.

In this case, in the inside of the rotary body 26, there are provided a diffraction beam splitter 94 for branching the laser beam LB reflected by the mirror 32 and a plurality of optical fibers 36 for guiding the laser beams LB branched by the diffraction beam splitter 94 to the plurality of condenser lenses 20.

In the second modification, the laser beam LB emitted by the laser oscillator 18 is reflected by the mirror 32 and is thereafter branched by the diffraction beam splitter 94, and the branched laser beams LB are applied to the ingot from the plurality of condenser lenses 20 through the plurality of optical fibers 36. Therefore, it is possible to more effectively form the modified layer inside the ingot.

(Third Modification)

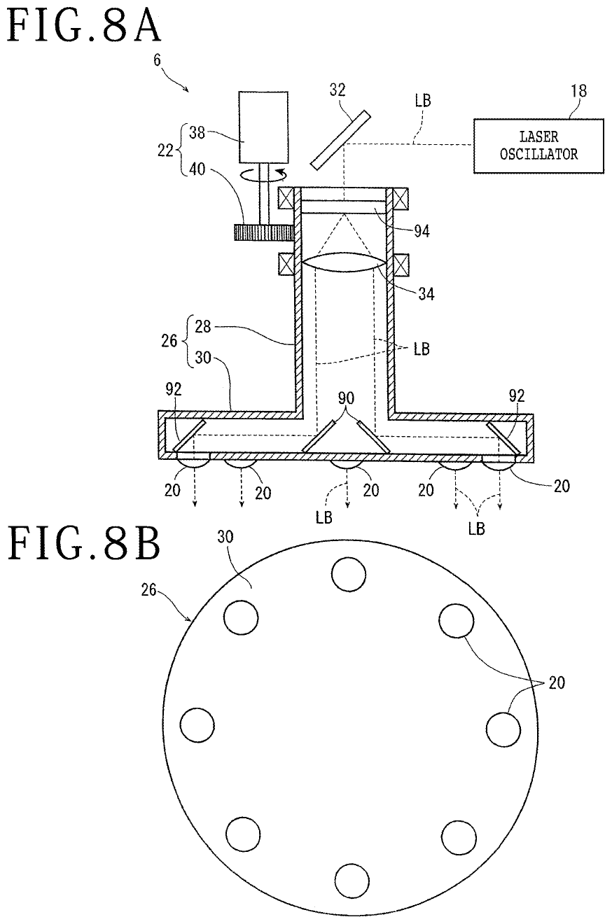

In addition, as in a third modification depicted in FIGS. 8A and 8B, there may be provided the plurality of condenser lenses 20 disposed at intervals in the rotating direction of the rotary body 26, the diffraction beam splitter 94 for branching the laser beam LB reflected by the mirror 32, and a plurality of sets of first and second mirrors 90 and 92 for guiding the laser beams LB branched by the diffraction beam splitter 94 to the plurality of condenser lenses 20.

In the third modification, eight condenser lenses 20 are disposed, and eight sets of the first and second mirrors 90 and 92 are provided, but, for the sake of convenience, two sets of the first and second mirrors 90 and 92 are depicted in FIG. 8A.

In the third modification, also, as in the second modification depicted in FIGS. 7A and 7B, the laser beam LB emitted by the laser oscillator 18 is reflected by the mirror 32 and is thereafter branched by the diffraction beam splitter 94, and the branched laser beams LB are applied to the ingot from the plurality of condenser lenses 20 through the plurality of sets of first and second mirrors 90 and 92. Therefore, it is possible to more effectively form the modified layer inside the ingot.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer manufacturing apparatus comprising:
a holding table that holds an ingot;
a wafer manufacturing unit that applies such a laser beam as to be transmitted through the ingot to the ingot, with a focal point of the laser beam positioned inside the ingot, to form a modified layer at a depth corresponding to a thickness of a wafer to be manufactured; and
a moving mechanism that moves the holding table and the wafer manufacturing unit relative to each other,
wherein the wafer manufacturing unit includes
a laser oscillator that emits the laser beam,
a condenser lens that concentrates the laser beam emitted by the laser oscillator, to the inside of the ingot, and
a rotating mechanism that rotates the condenser lens in parallel to an end face of the ingot.

2. The wafer manufacturing apparatus according to claim 1, wherein a plurality of the condenser lenses are disposed in a rotating direction.
